(19) United States
(12) Patent Application Publication
(10) Pub. No.: US 2023/0126912 A1
(43) Pub. Date: Apr. 27, 2023

(54) PLASMA CVD APPARATUS WITH A BEVEL MASK WITH A PLANAR INNER EDGE

(71) Applicant: ASM IP Holding B.V., Almere (NL)

(72) Inventor: Ryo Miyama, Tokyo (JP)

(21) Appl. No.: 17/971,829

(22) Filed: Oct. 24, 2022

Related U.S. Application Data
(60) Provisional application No. 63/272,287, filed on Oct. 27, 2021.

(51) Int. Cl. C23C 16/509; H01J 37/32; C23C 16/458; C23C 16/04

(52) U.S. Cl. CPC C23C 16/509; C23C 16/042; C23C 16/4586; H01J 37/32715; H01J 37/32568; H01J 2237/3321; H01L 21/6833

(57) ABSTRACT

A bevel mask for use in plasma CVD apparatus for depositing a more uniform film while preventing film peeling at the edges of the wafer. The bevel mask includes a bulk portion and an edge portion. The bulk portion includes an inner beveled surface or face, and the edge portion extends outward from a bottom section of the inner beveled surface to provide a covering for a peripheral portion of the upper surface of a wafer received on the susceptor, which supports the annular-shaped mask such as upon a ring structure on an upper surface of the susceptor.

### CROSS-REFERENCE TO RELATED APPLICATIONS

This application claims priority to U.S. Provisional Patent Application Serial No. 63/272,287 filed Oct. 27, 2021 titled PLASMA CVD APPARATUS WITH A BEVEL MASK WITH A PLANAR INNER EDGE, the disclosure of which is hereby incorporated by reference in its entirety.

### FIELD OF THE DISCLOSURE

The present disclosure relates generally semiconductor manufacturing and corresponding systems for performing the manufacturing, and, more particularly, to a plasma chemical vapor deposition (CVD) apparatus for forming a film on a substrate (e.g., a wafer) with enhanced film uniformity across the entire substrate including the outer edge of the substrate.

### BACKGROUND OF THE DISCLOSURE

In the semiconductor industry, plasma or plasma-enhanced CVD (which may be labeled plasma CVD or PECVD) is widely used to fabricate semiconductor structures. In general, “chemical vapor deposition” (CVD) may refer to any process in which a substrate (e.g., a wafer) is exposed to one or more volatile precursors, which react and/or decompose on a substrate surface to produce a desired deposition. Thermal and plasma CVD is common throughout the semiconductor industry.

With regard to plasma CVD, FIG. 1 is a schematic view of a conventional plasma CVD processing apparatus 1. The apparatus 1 includes a reaction chamber 6, a gas inlet port 5, a circular upper electrode 9, and a lower electrode made up of a susceptor (or top plate) 3 and a heater 2. From a gas line (not shown), a gas introduced through the gas inlet port 5. The circular upper electrode 9 is disposed directly below the gas inlet port 5. The upper electrode 9 has a hollow structure and a number of fine pores provided at is bottom from which the gas is jetted out toward a substrate or wafer 4 supported on an upper surface of the susceptor 3. The upper electrode 9 includes a shower plate 11 in which these holes or pores are provided, and this plate 11 is replaceable so as to facilitate maintenance work and to reduce component costs.

Additionally, at the bottom of the reaction chamber 6, an exhaust port 10 is provided. This exhaust port is connected to an external vacuum pump (not shown), and the interior of the reaction chamber 6 is exhausted during plasma CVD operations. The susceptor or substrate support 3 is disposed parallel to and facing the upper electrode or showerhead 9. The susceptor 3 supports the wafer 4, heats the wafer 4 via the heater 2, and maintains the wafer 4 at desired deposition temperatures (e.g., in the range of about 50 to about 650° C.). The gas inlet port 5 and the upper electrode 9 are electrically insulated from the reaction chamber 6 and connected to an external first radio frequency (RF) power source 7 along with a second RF power source 8 in this exemplary configuration of apparatus 1. Grounding 12 of the chamber 6 is also provided. Hence, to achieve plasma CVD operations, the upper electrode 9 and lower electrode function as RF electrodes and generate a plasma reaction field in the vicinity of the wafer 4. The type and characteristics of a resulting film formed on the wafer 4 vary depending on the type and flow rate of the source gas, the temperature in the reaction chamber 6, the RF frequency, the plasma space distribution, and electric potential distribution.

In the conventional plasma CVD provided by apparatus 1, a film can be undesirably formed on a peripheral portion of the top surface of the wafer 4 and also on a side portion of the wafer 4 as well, in some cases, particles depending on the process. Hence, there have been demands for different designs for plasma CVD apparatus (e.g., modifications for apparatus 1 of FIG. 1) that will prevent or at least limit film formation on these portions of the wafer and, in particular, will address peeling of a film at a wafer edge that causes defect problems.

In some thermal CVD apparatus designs, a shield or seal ring was provided that was in contact with the wafer and that was configured to cover a periphery of the wafer. However, it was understood within the semiconductor industry that this design would not be useful with plasma CVD as abnormal film growth would occur in the vicinity of the mask, thereby causing poor uniformity of film thickness and other fabrication issues. To address issues with the use of a contacting ring or shield, CVD apparatus were designed that included masks that were spaced apart from the wafer and that had beveled inner edges. These new bevel masks proved useful in many applications, and, in particular, bevel masks generally prevented deposition at the bevel and the peeling of the film deposited upon the wafer.

Any discussion of problems and solutions set forth in this section has been included in this disclosure solely for the purpose of providing a context for the present disclosure and should not be taken as an admission that any or all of the discussion was known at the time the invention was made.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

FIG. 2 illustrates a portion of a plasma CVD apparatus with a bevel mask 220 is provided to reduce a film at or below the bevel or edge portion 224 of the mask 220. As shown, a wafer 204 is supported upon an upper surface of a susceptor 210, and the body or bulk portion 222 of the mask 220 is supported upon the susceptor 210 or, as shown, upon a ring 214 that extends about the periphery of the susceptor 210 so as to be spaced apart from the outer edge of the wafer 204. The ring (or a raised peripheral portion of the susceptor 210) 214 supports the bevel mask 220 a distance above the upper surface of the wafer 204 with the bevel or edge portion 224 extending over a peripheral portion or outer edge portion of the wafer 204. Particularly, as shown, the outer diameter, D_{Wafer}, of the wafer 204 is greater than the inner diameter, D_{Mask}, of the mask 220 (as measured from the central axis of the susceptor 210 to an inner edge/side of the bevel or edge portion 224). This configuration for a bevel mask is shown and described in further detail in U. S. Pat. Appl. Publ. No. 2007/0065597, which is incorporated by reference herein in its entirety.

The inventor recognized that such a bevel mask reduces a film at the bevel and prevents peeling, but the bevel mask negatively affects uniformity of thickness of the deposited film. FIG. 3 is a graph 300 of normalized film thickness, with line 310, relative to the wafer diameter, and a thickness non-uniformity is shown at encircled portion 315 corresponding to the outer edge of the wafer (with the graph being provided for a wafer with a 300 mm outer diameter). The graph 300 shows the thickness profile with line 310 for a gap fill carbon process (or operation of a plasma CVD apparatus) using the bevel mask 220 of FIG. 2. The thickness around the wafer radius of 145 to 150 mm is non-uniform due to the presence of the mask, and this can cause a lower yield during device fabrication.

According to some aspects of the description, a plasma deposition apparatus (e.g., a chemical vapor deposition (CVD) apparatus) is provided for forming a thin film on a wafer. The apparatus includes a reaction or vacuum chamber and a plasma generation electrode (e.g., a radio frequency (RF) electrode) in or coupled to the chamber. The apparatus further includes a susceptor for supporting a wafer, and the susceptor is provided in the vacuum chamber and has an electrode therein (e.g., the lower electrode of the electrode pair to support creating a plasma). The apparatus also includes a mask including a bulk portion extending about a periphery of the wafer. The bulk portion includes a beveled surface facing into the vacuum chamber, and the mask further includes an edge portion extending outward from the beveled surface to cover a peripheral portion of an upper surface of the wafer.

In some implementations of the apparatus, the edge portion has a planar cross sectional shape and is arranged to be parallel to the top surface of the wafer and/or of the susceptor. The edge portion may have a width of at least 1 millimeter (mm) and less than or equal to 6 millimeters and may have a thickness of at least 0.15 mm and less than or equal to 1 mm. In some cases, the susceptor includes a ring structure with an inner wall defining a pocket for receiving the wafer, and a clearance between an outer edge of the wafer and the inner wall is less than 3 mm.

In these and other embodiments of the CVD apparatus, the edge portion has an internal diameter that is less than an outer diameter of the wafer and greater than or equal to the outer diameter of the wafer minus 10 mm. The bulk portion has a minimum thickness greater than or equal to a thickness of the edge portion. Further, it may be useful for there to be a gap or clearance between a lower surface of the edge portion and an upper surface of the wafer that is less than or equal to 1 mm.

The mask may be fabricated or composed of aluminum oxide or aluminum nitride. In these and other implementations of the apparatus, the thin film formed on the wafer includes carbon and hydrogen. The beveled surface has a bevel angle as measured from a top surface of the susceptor in the range of 10 to 45 degrees, such as 20 to 30 degrees in some cases.

According to some aspects of the description, a plasma deposition apparatus is provided for forming a thin film on a wafer. The apparatus includes a vacuum chamber and a plasma generation electrode in or coupled to the vacuum chamber. The apparatus further includes a susceptor for supporting a wafer, and the susceptor is provided in the vacuum chamber and has an electrode therein. A mask is also provided in the apparatus that includes a bulk portion extending about a periphery of the wafer. The bulk portion includes a beveled surface facing into the vacuum chamber, and the mask further includes an edge portion extending outward from the beveled surface to cover a peripheral portion of an upper surface of the wafer.

In some implementations of the apparatus, the edge portion has a planar cross sectional shape. The edge portion may have a width of at least 1 millimeter (mm) and less than or equal to 6 millimeters and may have a thickness of at least 0.15 mm and less than or equal to 1 mm. In some embodiments, the susceptor includes a ring structure with an inner wall defining a pocket for receiving the wafer and wherein a clearance between an outer edge of the wafer and the inner wall is less than 3 mm. Further, the bulk portion may have a minimum thickness greater than or equal to a thickness of the edge portion.

It can be useful in the apparatus for there to be provided a gap or a clearance between a lower surface of the edge portion and an upper surface of the wafer that is less than or equal to 1 mm. In these and other embodiments of the apparatus, the mask may be composed of aluminum oxide or aluminum nitride. Further, the mask may be useful when the thin film formed on the wafer comprises carbon and hydrogen. Additionally, the apparatus may be beneficially implemented with the edge portion parallel to a top surface of the susceptor and with the beveled surface having a bevel angle as measured from a top surface of the susceptor in the range of 10 to 45 degrees.

For the purpose of summarizing the disclosure and the advantages achieved over the prior art, certain objects and advantages of the disclosure have been described herein above. Of course, it is to be understood that not necessarily all such objects or advantages may be achieved in accordance with any particular embodiment of the disclosure. Thus, for example, those skilled in the art will recognize that the embodiments disclosed herein may be carried out in a manner that achieves or optimizes one advantage or group of advantages as taught or suggested herein without necessarily achieving other objects or advantages as may be taught or suggested herein.

All of these embodiments are intended to be within the scope of the disclosure. These and other embodiments will become readily apparent to those skilled in the art from the following detailed description of certain embodiments having reference to the attached figures, the disclosure not being limited to any particular embodiment(s) discussed.

### BRIEF DESCRIPTION OF THE DRAWING FIGURES

While the specification concludes with claims particularly pointing out and distinctly claiming what are regarded as embodiments of the disclosure, the advantages of embodiments of the disclosure may be more readily ascertained from the description of certain examples of the embodiments of the disclosure when read in conjunction with the accompanying drawings. Elements with the like element numbering throughout the figures are intended to be the same.

FIG. 1 is a side sectional view of a conventional plasma CVD apparatus.

FIG. 2 illustrates is a side schematic view illustrating details of a prior bevel mask for use in a plasma CVD apparatus such as the apparatus of FIG. 1.

FIG. 3 illustrates a graph of film thickness relative to wafer diameter for a plasma CVD process in which a bevel mask such as the one shown in FIG. 2 is used to limit film peeling.

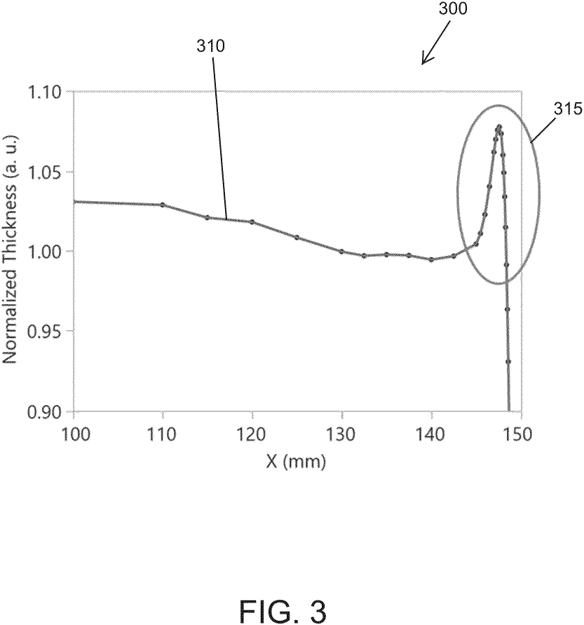

FIG. 4 illustrates a side schematic view, similar to FIG. 2, of a bevel mask with a planar inner edge or bevel extension according to the present description.

FIG. 5 illustrates a graph of film thickness relative to wafer diameter showing thickness profiles at a wafer edge for the conventional bevel mask of FIG. 2 and the new mask of FIG. 4.

FIG. 6 illustrates a graph of film thickness relative to wafer diameter showing thickness profiles at a wafer edge for two different embodiments of the mask of FIG. 4.

FIG. 7 illustrates a side sectional view of a plasma CVD apparatus according to the present description.

### DETAILED DESCRIPTION

Although certain embodiments and examples are disclosed below, it will be understood by those in the art that the disclosure extends beyond the specifically disclosed embodiments and/or uses of the disclosure and obvious modifications and equivalents thereof. Thus, it is intended that the scope of the disclosure should not be limited by the particular embodiments described herein.

The illustrations presented herein are not meant to be actual views of any particular material, apparatus, structure, or device, but are merely representations that are used to describe embodiments of the disclosure.

As used herein, the term “substrate” and “wafer” may be used interchangeably and may refer to any underlying material or materials that may be used, or upon which, a device, a circuit, or a film may be formed.

As used herein, the term “chemical vapor deposition” (CVD) may refer to any process wherein a substrate is exposed to one or more volatile precursors, which react and/or decompose on a substrate surface to produce a desired deposition.

As used herein, the term “film” and “thin film” may refer to any continuous or non-continuous structures and material deposited by the methods disclosed herein. For example, “film” and “thin film” could include 2D materials, nanorods, nanotubes, or nanoparticles or even partial or full molecular layers or partial or full atomic layers or clusters of atoms and/or molecules. “Film” and “thin film” may comprise material or a layer with pinholes, but still be at least partially continuous.

As described in greater detail below, various details and embodiments of the disclosure may be utilized in conjunction with a reaction chamber configured for a multitude of deposition processes, including but not limited to plasma-enhanced chemical vapor deposition (PECVD or plasma CVD).

Briefly, a new bevel mask design is described herein for use within plasma CVD reaction chambers. The new bevel mask design includes an inner edge portion or extension that is planar or flat in profile or cross sectional shape and that extends inward from the bevel or beveled surface or side of the body or bulk portion of the mask. The dimensions of the mask and its positioning on the susceptor are such that the inner edge portion extends over at least a portion of the outer edge of a wafer supported upon the susceptor while the bevel or beveled surface is typically offset from the wafer outer edge (e.g., has its outer edge or side located above the gap or spacing between the wafer edge and the portion of the susceptor supporting the mask, which may be an integral part of the susceptor or a ring provided on the periphery of the susceptor). The new mask has been proven to enhance the uniformity of a film deposited upon the wafer in plasma CVD processes while still preventing or controlling peeling of the film.

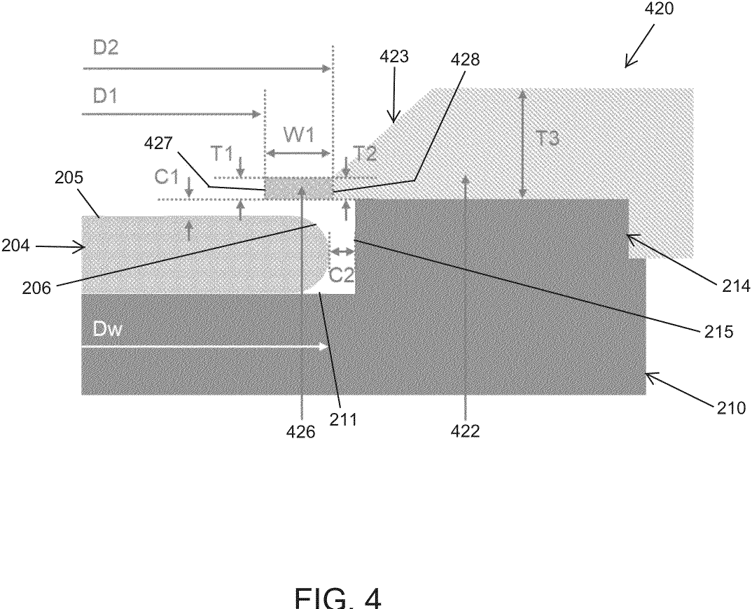

FIG. 4 illustrates a side sectional view of a portion of a plasma CVD reaction chamber in which the new mask design is implemented. As shown, a susceptor or substrate support 210 is provided and a wafer 204 is placed upon an upper surface 211 of the susceptor 210. An upper or top surface 205 of the wafer 204 is facing upward or toward a showerhead (not shown) in a chamber. The susceptor 210 includes a raised peripheral element or ring 214 about its peripheral or outer edge (with the wafer 204 received within the recessed surface or pocket defined by an inner wall 215 of the ring 214), and a bevel mask 420 is supported upon the ring 214 during deposition operations of a reaction chamber in which the susceptor 210 is located.

The new mask design, as shown, calls for the bevel mask 420 includes a body or bulk portion 422, which is positioned over the ring 214. The bevel mask 420 also includes a bevel or beveled inner side or surface 423 facing inward toward the center of the reaction chamber (or center axis of the susceptor 210), and the bevel 423 is generally positioned over the ring 214 with its inner end cantilevered outward from the ring to be positioned over a gap or space between an outer edge 206 of the wafer 204 and an inner wall 215 of the ring 214.

Significantly, the bevel mask 420 includes an inner edge portion or extension 426 that extends outward from the bevel 423 from a first end 428 attached to the bulk portion 422 to a second end 427. In this way, the inner edge portion 426 is positioned over the outer edge 206 and an outer portion of the upper surface 205 of the wafer 204. As shown, the inner edge portion 426 is generally planar in its profile or cross sectional shape, e.g., with the thickness, T1, at the second end 427 equal to or only some smaller amount less than the thickness, T2, at the first end 428. The thickness, T2, may also be thought of as the minimum thickness of the bulk portion 422 of the mask with T1 being the uniform thickness of the edge portion 426 of the mask 420. The bevel mask 420 is annular in overall shape, with an inner diameter (or internal diameter of the edge portion 426), D1, defining a size of the inner hole over the susceptor 210 and any received wafer 204. The mask 420 typically will be integrally formed (e.g., cast) of a material useful in a plasma CVD reaction chamber such as aluminum oxide, aluminum nitride, aluminum, silicon, silicon oxide, silicon carbide, silicon nitride, and metal impregnated ceramic.

The specific shapes and dimensions used to fabricate the bevel mask 420 may be varied to implement a useful reaction chamber to limit peeling and provide more uniform film thicknesses, but it may be useful to provide some useful working examples. The internal diameter, D1, of the edge portion 426 may be chosen so as to be within about 10 millimeters (mm) of an outer diameter, Dw, of the wafer 204. For example, the internal diameter, D1, may be in the range of 290 to 300 mm when the wafer 204 has an outer diameter, Dw, of 300 mm. The internal diameter, D2, of the bulk portion 422 (e.g., inner edge of bevel 423) may be given by the equation D2 = D1 + 2xW1, where W1 is the width of the edge portion 426 and W1 may be in the range of 1 to 6 mm in many applications such that D2 would be in the range of 292 to 312 mm when the mask 420 is made for use with a 300-mm wafer 204.

The thickness, T1, of the inner edge portion 426 may be chosen to be in the range of about 0.15 to about 1 mm, with the minimum thickness, T2, of the bulk portion 422 being greater than T1 and with the maximum thickness, T3, of the bulk portion being greater than T2. The gap or clearance, C1, between the bottom or lower surface of the inner edge portion 426 and the upper surface 205 of the wafer 204 may be zero (i.e., contacting) to about 1 mm. The gap or clearance, C2, between the outer edge 206 of the wafer and the inner wall 215 of the ring 214 may be zero (i.e., contacting) to about 3 mm. The body of the edge portion 426 is parallel to the upper surface 205 of the wafer in many implementations, and the bevel 423 may be provided at an angle of 10 to 45 degrees, with 20 to 30 degrees being useful in some cases, as measured from a top surface 205 of the wafer 204 or a top surface 211 of the susceptor 210.

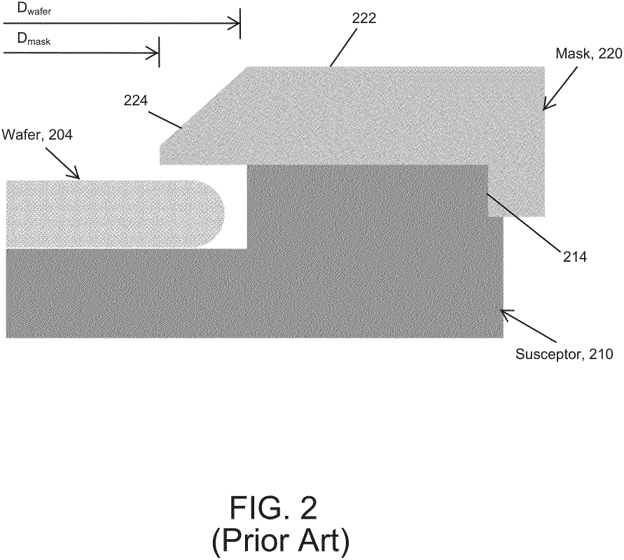

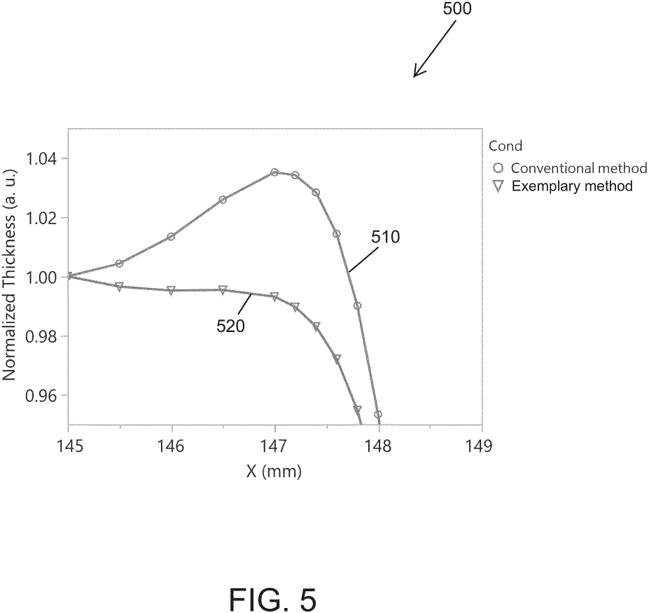

FIG. 5 shows with graph 500 normalized film thickness relative to radius of a wafer to provide thickness profiles 510, 520 with a conventional bevel mask 220 as shown in FIG. 2 and with the new bevel mask 420 of FIG. 4. In these deposition results, the internal diameters of both masks were the same, but the deposition results differed significantly. Particularly, from wafer radii from 147 to 148 mm (for a wafer with a 300 mm outer diameter), the thickness with both bevel masks decreased because the bevel masks prevent the deposition at the wafer edge. However, from wafer radii from 145 to 147 mm, the film thickness with the conventional mask increase, which worsens the uniformity. One likely reason for this thickness increase is that the conventional bevel mask blocks the gas flow. The gas residence time nearby the mask is relatively longer than the inward areas. The probability of the dissociation of the precursor nearby the mask increased and the flux of the deposition species increases at the area.

In contrast, as shown with in FIG. 5, the thickness profile 520 with the proposed mask 420 stays flat between wafer radii of 145 to 147 mm. This desirable result is likely because the shape of the edge portion 426 affects the profile 520. As discussed above, the bevel mask 420 includes an edge portion 426 and a bulk portion 422 with bevel 423. The edge portion 426 is planar or nearly flat and much thinner than the inner portions of the conventional bevel mask. The planar and thin edge shape improves the gas flow nearby the mask 420, and, therefore, the gas residence time at the area of the mask 420 above the outer portions of the wafer 204 becomes equal (or nearer to equal) to the other areas of the wafer 204.

To generate the results of graph 500, the conventional mask 220 was fabricated with a minimum thickness of 0.3 mm and a maximum bulk portion thickness of 3.0 mm. The clearance between the mask and the upper surface of the wafer was zero, and the internal diameter of the mask was 299 mm. The new bevel mask 420 has a width, W1, of 3.5 mm and a thickness, T1, of 0.3 mm. The bulk portion 422 had a thickness, T3, of 3.0 mm, while the clearance C1 between the edge portion’s lower surface and the upper surface 205 of the wafer 204 was set to 0 mm. The internal diameter, D1, of the edge portion 426 was set to 299 mm while the internal diameter, D2, of the bulk portion 422 was set to 306 mm (i.e., the edge portion width, W1, was 7 mm). The deposition process was a cyclic process of deposition and treatment with 34 cycles, pressure at 1100 Pa, and a process gap of 8.0 mm. Deposition was BTL1-He(alpha-7)/BTL2-He/Dil-He=2.6/2.6/0.5 slm, RF 82 W, and 5.5 second duration while the treatment was BTL1-He/BTL2-He/Dil-He=2.6/2.6/0.5 slm, RF 380W, and 5.0 second duration.

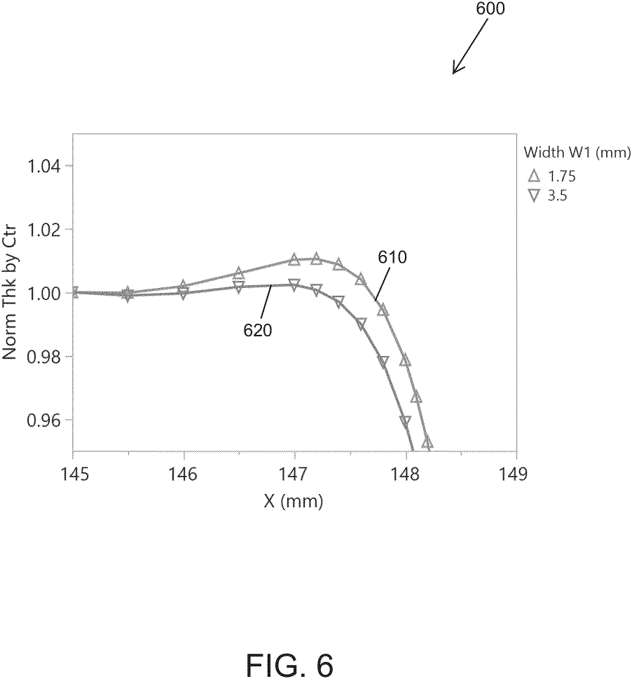

FIG. 6 illustrates a graph 600 of nominal film thickness versus wafer radii that shows the thickness profiles 610 and 620 with a bevel mask with edge portion thicknesses of 1.75 mm and 3.5 mm, respectively. The profiles 610 and 620 show the impact of the width, W1, of the edge portion 426 on the thickness of the deposited film. A larger width, W1, makes the profile 620 flatter than the profile 610. That is likely because the greater width, W1, improves the gas flow, and, hence, in many implementations, a width, W1, of 2.5 to 6 mm, of 3.5 to 6 mm, and of 4.5 to 6 mm may be desirable to better achieve uniform thickness at or near wafer edge.

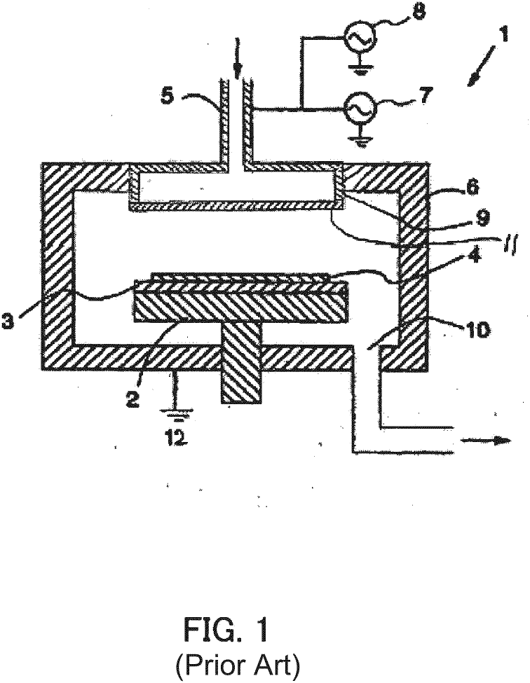

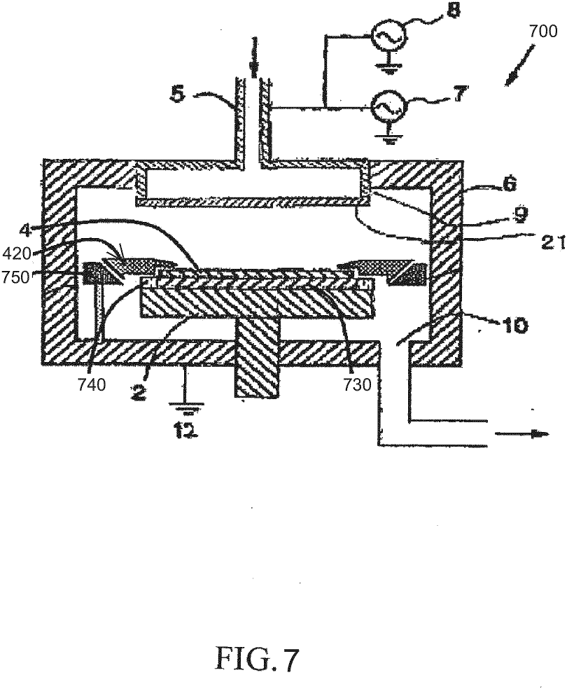

FIG. 7 illustrates a side sectional view of a plasma CVD apparatus 700 according to the present description. The apparatus 700 includes components similar to those found in apparatus 1 of FIG. 1, and like reference numbers are used to refer these components and the above description of these components is applicable to apparatus 700. Briefly, though, the plasma CVD apparatus 700 includes a reaction chamber 6, a gas inlet port 5, an upper (or RF) electrode 9, and a lower electrode including a susceptor 730 (e.g., the susceptor 730 may have an electrode therein) and a heater 2. From a gas line (not shown), a gas is introduced through the gas inlet port 5. The circular upper electrode 9 is disposed directly below the gas inlet port 5. The upper electrode 9 has a hollow structure and a number of fine pores provided at its bottom from which a gas is jetted out toward the wafer 4. The upper electrode 9 has a structure in which a shower plate 21 having a plurality of gas inlet holes is replaceable to facilitate maintenance.

Additionally, at the bottom of the reaction chamber 6, an exhaust port 10 is provided that is connected to an external vacuum pump (not shown). During operation of the apparatus 700, the interior of the reaction chamber 6 is exhausted. The susceptor 730 is disposed parallel to and facing the upper electrode, and the susceptor 730 holds a wafer 4 thereon, heats the wafer via operation of the heater 2, and maintains the wafer at a temperature within a desired range. A peripheral portion or ring structure 740 of (or provided on) the susceptor 730 is formed of alumina in some embodiments and is used to support the bevel mask 420 of the present description (see FIG. 4 for a particular useful profile or cross sectional shape).

As shown, the mask 420 is disposed about the periphery of the wafer 4 with the inner edge portion covering outer portions of the upper surface of the wafer 4. When the susceptor 730 is moved downward by a vertical movement by a vertical movement mechanism (not shown but understood by those in the arts), the mask 420 is placed on a mask-supporting stand 750. When the susceptor 730 is moved upward by the vertical movement mechanism, the mask 420 is placed on the ring structure 740 on the susceptor 730. The deposition process then may proceed via operations of the apparatus 700 with the mask 420 acting to enhance uniform deposition of a film on the upper surface of the wafer 4.

Benefits, other advantages, and solutions to problems have been described herein with regard to specific embodiments. However, the benefits, advantages, solutions to problems, and any elements that may cause any benefit, advantage, or solution to occur or become more pronounced are not to be construed as critical, required, or essential features or elements of the disclosure.

Furthermore, the described features, advantages, and characteristics of the disclosure may be combined in any suitable manner in one or more embodiments. One skilled in the relevant art will recognize that the subject matter of the present application may be practiced without one or more of the specific features or advantages of a particular embodiment. In other instances, additional features and advantages may be recognized in certain embodiments that may not be present in all embodiments of the disclosure. Further, in some instances, well-known structures, materials, or operations are not shown or described in detail to avoid obscuring aspects of the subject matter of the present disclosure. No claim element is intended to invoke 35 U.S.C. 112(f) unless the element is expressly recited using the phrase “means for.”

The scope of the disclosure is to be limited by nothing other than the appended claims, in which reference to an element in the singular is not intended to mean “one and only one” unless explicitly so stated, but rather “one or more.” It is to be understood that unless specifically stated otherwise, references to “a,” “an,” and/or “the” may include one or more than one and that reference to an item in the singular may also include the item in the plural. Further, the term “plurality” can be defined as “at least two.” As used herein, the phrase “at least one of”, when used with a list of items, means different combinations of one or more of the listed items may be used and only one of the items in the list may be needed. The item may be a particular object, thing, or category. Moreover, where a phrase similar to “at least one of A, B, and C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A, B, and C. In some cases, “at least one of item A, item B, and item C” may mean, for example, without limitation, two of item A, one of item B, and ten of item C; four of item B and seven of item C; or some other suitable combination.

All ranges and ratio limits disclosed herein may be combined. Unless otherwise indicated, the terms “first,” “second,” etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

Although exemplary embodiments of the present disclosure are set forth herein, it should be appreciated that the disclosure is not so limited. For example, although reactor systems are described in connection with various specific configurations, the disclosure is not necessarily limited to these examples. Various modifications, variations, and enhancements of the system and method set forth herein may be made without departing from the spirit and scope of the present disclosure.

What is claimed is:

1. A plasma deposition apparatus for forming a thin film on a wafer, comprising:
a vacuum chamber;
a plasma generation electrode in or coupled to the vacuum chamber;
a susceptor for supporting a wafer, wherein the susceptor is provided in the vacuum chamber and has an electrode therein; and
a mask including a bulk portion extending about a periphery of the wafer, wherein the bulk portion includes a beveled surface facing into the vacuum chamber and wherein the mask further includes an edge portion extending outward from the beveled surface to cover a peripheral portion of an upper surface of the wafer.

2. The apparatus of claim 1, wherein the edge portion has a planar cross sectional shape.

3. The apparatus according to claim 1, wherein the edge portion has a width of at least 1 millimeter (mm) and less than or equal to 6 millimeters.

4. The apparatus according to claim 1, wherein the edge portion has a thickness of at least 0.15 mm and less than or equal to 1 mm.

5. The apparatus according to claim 1, wherein the susceptor includes a ring structure with an inner wall defining a pocket for receiving the wafer and wherein a clearance between an outer edge of the wafer and the inner wall is less than 3 mm.

6. The apparatus according to claim 1, wherein the edge portion has an internal diameter that is less than an outer diameter of the wafer and greater than or equal to the outer diameter of the wafer minus 10 mm.

7. The apparatus according to claim 1 wherein the bulk portion has a minimum thickness greater than or equal to a thickness of the edge portion.

8. The apparatus according to claim 1, wherein a clearance between a lower surface of the edge portion and an upper surface of the wafer is less than or equal to 1 mm.

9. The apparatus according to claim 1, wherein the mask is composed of aluminum oxide or aluminum nitride.

10. The apparatus according to claim 1, wherein the thin film formed on the wafer comprises carbon and hydrogen.

11. The apparatus according to claim 1, wherein the edge portion is parallel to a top surface of the susceptor.

12. The apparatus according to claim 1, wherein the beveled surface has a bevel angle as measured from a top surface of the susceptor in the range of 10 to 45 degrees.

13. A plasma deposition apparatus for forming a thin film on a wafer, comprising:
a reaction chamber;
a susceptor disposed within the reaction chamber for supporting a wafer; and
an annular-shaped mask supported on the susceptor, wherein the annular-shaped mask includes a bulk portion and an edge portion, wherein the edge portion extends outward from the bulk portion adjacent a bevel to cover an outer portion of an upper surface of the wafer, and wherein the edge portion has a planar cross sectional shape and extends parallel to the upper surface of the wafer.

14. The apparatus according to claim 13, wherein the edge portion has a width of at least 1 millimeter (mm) and less than or equal to 6 millimeters.

15. The apparatus according to claim 13, wherein the edge portion has a thickness of at least 0.15 mm and less than or equal to 1 mm.

16. The according to claim 13, wherein the susceptor includes a ring structure with an inner wall defining a pocket for receiving the wafer and wherein a clearance between an outer edge of the wafer and the inner wall is less than 3 mm.

17. The apparatus according to claim 13, wherein the edge portion has an internal diameter that is less than an outer diameter of the wafer and greater than or equal to the outer diameter of the wafer minus 10 mm.

18. The apparatus according to claim 13, wherein a clearance between a lower surface of the edge portion and an upper surface of the wafer is less than or equal to 1 mm.

19. The apparatus according to claim 13, wherein the mask is composed of at least one of aluminum oxide, aluminum nitride, aluminum, silicon, silicon oxide, silicon carbide, silicon nitride, and metal impregnated ceramic.

20. A plasma deposition apparatus for forming a thin film on a wafer, comprising:
a vacuum chamber;
a plasma generation electrode in or coupled to the vacuum chamber;
a susceptor for supporting a wafer, wherein the susceptor is provided in the vacuum chamber and has an electrode therein; and
a mask including a bulk portion extending about a periphery of the wafer and an edge portion extending outward from an inner edge of the bulk portion to cover a peripheral portion of an upper surface of the wafer, wherein the edge portion has a width of at least 1 millimeter (mm) and less than or equal to 6 millimeters and wherein the edge portion has an internal diameter that is less than an outer diameter of the wafer.
